(19) United States
(12) Patent Application Publication
(10) Pub. No.: US 2017/0232701 A1
(43) Pub. Date: Aug. 17, 2017

(54) THIN GLASS FILM COMPOSITE WEB WITH REINFORCING STRIPS

(71) Applicant: TESA SE, Norderstedt (DE)

(72) Inventors: Klaus KEITE-TELGENBÜSCHER, Hamburg (DE); Julia ROMPF, Hamburg (DE); Manuel BENDEICH, Hamburg (DE)

(73) Assignee: TESA SE, Norderstedt (DE)

(21) Appl. No.: 15/518,916

(22) PCT Filed: Sep. 18, 2015
(86) PCT No.: PCT/EP2015/071498

§ 371 Date: Apr. 13, 2017

(30) Foreign Application Priority Data
Oct. 20, 2014 (DE) 10 2014 221 245.6

(51) Int. Cl. B32B 3/08; B32B 7/06; B32B 17/06; H01L 51/00; B32B 7/12

(52) U.S. Cl. CPC B32B 3/085; H01L 51/0097; B32B 7/12; B32B 17/064; B32B 7/06; B32B 2307/54; B32B 2307/51; B32B 2307/7246; B32B 2457/00

(57) ABSTRACT

A thin glass film composite web comprising a thin glass film web (10) with a first surface (11), and a second surface (12), and two edges (15, 16) which run in the longitudinal direction (L) and comprising a protective film web (20) made of a first material, said protective film web extending along at least one part of the first surface (11), at least one reinforcing strip (30, 31) made of a second material which differs from the first material, said reinforcing strip running along at least one of the two edges (15, 16), the protective film web and the reinforcing strip being connected to each other such that the two can together be applied onto the thin glass web, and the at least one reinforcing strip (30, 31) having a greater relative tensile strength than the thin glass film web (10).

This application is a 371 of PCT/EP2015/071498, filed Sep. 18, 2015, which claims foreign priority benefit under 35 U.S.C. §119 of the German Patent Application No. 10 2014 221 245.6 filed Oct. 20, 2014, the disclosures of which patent applications are incorporated herein by reference.

### BACKGROUND OF THE INVENTION

The invention concerns a thin glass film composite web according to the generic concept of claim 1 and a method for the storage of thin glass film webs.

Optoelectronic devices are being used with increasing frequency in commercial products or will soon be introduced onto the market. Such devices comprise inorganic or organic electronic structures such as organic, organometallic, or polymeric semiconductors or combinations thereof. Depending on the desired application, the corresponding products have a stiff or flexible configuration, and there is an increasing demand for flexible devices. The production of such devices is often carried out by printing processes such as surface printing, roller printing, silkscreen printing, flat printing, or so-called “non-impact printing” processes such as thermal transfer printing, inkjet printing, or digital printing. However, vacuum processes such as chemical vapor deposition (CVD), physical vapor deposition (PVD), plasma-enhanced chemical or physical deposition processes (PECVD), sputtering, (plasma) etching, or vaporization are also used. Structuring is carried out by masking.

Examples of optoelectronic applications that are already commercially available or interesting in their market potential include electrophoretic or electrochromic structures or displays, organic or polymeric light-emitting diodes (OLEDs or PLEDs) in lighting and display devices or as illumination, as well as electroluminescent lamps, light-emitting electrochemical cells (LEECs), organic solar cells such as dye or polymer solar cells, inorganic solar cells, particularly thin-layer solar cells, for example based on silicon, germanium, copper, indium and selenium, perovskite solar cells, organic field effect transistors, organic elements, organic optical amplifiers, organic laser diodes, organic or inorganic sensors, or organically or inorganically based RFID transponders.

In the effort to achieve sufficient useful life and functioning of optoelectronic devices in the area of inorganic and organic optoelectronics, and particularly in organic optoelectronics, protection of the components contained therein from permeates is to be seen as a particular technical challenge. In this case, permeates are generally considered to be gaseous or liquid substances that penetrate into a solid and may pass or permeate through it. Accordingly, many low-molecular-weight organic or inorganic compounds can be permeates, with water vapor and oxygen being of particular importance in this connection.

A number of optoelectronic devices—particularly when organic materials are used—are sensitive to both water vapor and oxygen. Protection by means of encapsulation during the useful life of electronic devices is therefore necessary in order to prevent performance from decreasing over the period of use. If protection is insufficient, for example because of oxidation or hydrolysis processes, there may be sharp reductions in the luminosity of electroluminescent lamps (EL lamps) or organic light-emitting diodes (OLED), the contrast of electrophoretic displays (EP displays), or the efficiency of solar cells within a short period of time.

In inorganic and/or organic (opto)electronics, particularly in organic (opto)electronics, there is therefore a need for flexible substrates that protect electronic components and constitute a permeation barrier against permeates such as oxygen and/or water vapor.

Glass provides particularly favorable protection from permeates. For some time, therefore, highly thin and flexible types of glass have been available on the market, with the product Willow® Glass manufactured by Corning being an example. This extremely thin and flexible glass can be used for electronic structures, and may significantly change the form of mobile terminal devices such as smartphones and tablets.

Thin glass films are supplied as films 100 μm in thickness on 1 m wide rolls having a length of up to 300 m.

For mechanical stabilization purposes, a thin glass film is often equipped with a protective polymer film. The protective film may remain permanently on the glass, or may be removed prior to use of the OLEDs in the final application. Protective films are ordinarily applied using an adhesive to the thin glass film. Measures to maintain stability are of essential importance in wide-ranging use of thin glass on rolls; on the one hand, such measures serve in particular to prevent stress corrosion cracking during storage of the roll, and on the other, however, a further important aspect of stabilizing the thin glass film is stabilization of the glass edge.

In the method of producing the thin glass film by the so-called down-draw process, the edge is initially thickened as a border, cf. WO 00/41978 A1. However, the border makes it more difficult to wind the thin glass film onto a roll, because on the one hand, this thickening allows only a small bending radius to be achieved, and on the other hand, the layers do not lie against one another in planar fashion. As a rule, therefore, the border on the thin glass film is cut off prior to winding onto a roll. The cut edge then remains as an extremely sensitive area, from which glass cracks tend to propagate into the interior of the thin glass film. In the handling and separation processes to which thin glass films are subjected during production, highly precise positioning of the thin glass film is often required. In particular, in lateral web guidance of the thin glass film in a roll-to-roll process, particularly strong forces act on the edge, increasing the risk of web cracks.

Glass is known to show a strong permeation-blocking effect against water vapor and oxygen, and it is therefore suitable for the encapsulation of OLEDs, which are sensitive to water vapor and oxygen. Flexible or bendable OLEDs require flexible encapsulation, which can advantageously be achieved using a flexible thin glass film. Thin glass films are bendable to a limited extent, and are therefore also suitable for the production of flexible or bendable devices. However, the thin glass film is highly sensitive, and damage may occur, originating in particular from the glass edge of the thin glass film, especially when this glass edge has been cut. Devices and methods used for stabilization, particularly of the edge of the thin glass film, are known from the prior art.

WO 2011/014606 discloses a flexible polymeric glass coating that projects at its edge beyond the glass. The coating can cover the glass over its entire width, or over only a portion thereof. The coating material can be reinforced with polymer or glass fibers. The coating can be applied as a liquid or as a preformed film. Both polymers and metal, also in combination with a polymer, are suggested as materials for the preformed film. The flexible glass film projecting laterally on the glass film allows simpler handling, i.e. the glass film can be picked up and transported using the two lateral coating projections.

A drawback of the glass coating is that it has an elastic modulus that is less than that of glass, and it therefore yields to tensile loads in the longitudinal direction of the thin glass film, so that the load is transferred directly to the edge of the thin glass film. Moreover, reinforcing materials in the form of polymer or glass fibers are applied along the entire width of the glass coating, causing its overall flexibility to decrease. Even when glass or polymer fibers are added in the maximum amount of 30 percent by weight, which is common for coatings or polymer films, the overall elastic modulus of the glass coating remains significantly lower than that of the glass film itself.

WO 2008/069930 A2 discloses a composite material of a glass layer and a flexible polymeric carrier layer. The glass layer is arranged on the polymer layer, with the polymer layer as a carrier material projecting beyond the edges of the glass layer.

The drawback in this case as well is that the polymer layer has a significantly lower elastic modulus than that of the thin glass film and therefore yields to tensile stress at the edge of the thin glass film, causing the stress to be transferred to the edge of the glass.

U.S. Pat. No. 6,815,070 B1 describes a glass-plastic composite for stabilizing thin glass. The thin glass is coated with liquid polymers. The polymer layer is applied to a thin glass film by spinning, spraying, pouring, rolling, or dipping. The polymer coating can also enclose the edge of the thin glass. However, the coating is of a homogeneous material, and it is extremely thin at the edge, making it incapable of absorbing the tensile forces generated at the edge of the thin glass film during web guidance. In this case as well, the polymer coating enclosing the edge shows a significantly lower elastic modulus than that of the glass itself and therefore yields to tensile stress at the edge of the glass, causing the stress to be transferred to the edge of the thin glass film.

EP 2336048 A1 discloses composites of a thin glass film and a polymeric carrier film in which the carrier film extends beyond the thin glass in the direction of the web not only in the front and rear, but also laterally. A drawback in this case as well is that the flexible polymeric carrier film has a significantly lower elastic modulus than glass, and therefore yields to a tensile stress at the edge of the thin glass film, with the result that the stress is transferred to the edge of the glass, where it can lead to crack formation.

US 2010/0260964 A1 concerns a composite of a thin glass film and a carrier material wound onto a roll, with the carrier material extending laterally beyond the edges of the thin glass film in this case as well. The polymer carrier material or the protective film is/are configured homogenously over their entire surface.

U.S. Pat. No. 6,592,969 B1 also discloses a composite that can be wound onto a roll composed of a thin glass film and a carrier material, with the carrier material also extending laterally beyond the edges of the thin glass film. In this case as well, the carrier material is homogenously composed of the same material over its entire surface.

US 2005/0053768 A1 discloses a glass protective film having embossed protruding features. The protective film may consist of a composite of a smooth polymer layer and a rough layer of paper or fabric, or may also be a pure polymer layer. The embossing provides the protective film with areas of differing tensile strength, which, however, are randomly distributed over the surface and show areas of lower tensile strength precisely at the edge. Moreover, the protective film does not extend beyond the edges. Fabrics and paper as reinforcing materials show a significantly lower elastic modulus than glass and therefore yield to tensile stress at the edge of the glass, so that in this case as well, the stress is transferred to the edge of the glass. The protective film is not suitable for protecting the edge by absorbing tensile forces acting from the edge.

EP 2548730 A1 discloses a composite of a thin glass film and a polymer carrier material that can be wound onto a roll, with the carrier material extending laterally beyond the edges of the glass film. Again, in this case, the polymer carrier material has a significantly lower elastic modulus than that of the glass, and the polymer carrier material is composed of a single material over its entire length.

US 2013/0196163 A1 discloses a composite of a thin glass film wound onto a roll having a reinforcing layer, with the thickness of the reinforcing layer being selected so that when the composite is bent toward the glass side, the neutral surface does not lie within the glass layer. This is the case when the thickness of the reinforcing layer is greater than the thickness of the thin glass film multiplied by the root of the quotient of the elastic modulus of the glass divided by the elastic modulus of the reinforcing layer. A drawback is that because of the high tensile strength of the entire reinforcing layer, the resulting composite is extremely rigid, i.e., the flexibility of the composite material is significantly reduced compared to the pure glass film.

The object of the invention is to provide a thin glass film composite web that allows improved protection of the edge of the thin glass film and nevertheless does not excessively increase bending stiffness.

It is also the object of the invention to provide a method for the storage of a thin glass film web.

### SUMMARY OF THE INVENTION

In its first aspect, the object is achieved by means of the thin glass film composite web mentioned above that has the characterizing features of claim 1.

The object is achieved in its second aspect by a method having the features of claim 16.

The thin glass film composite web according to the present invention has a thin glass film web with a first and second surface and two thin glass film edges running in the longitudinal direction of the thin glass film web. The thin glass film composite web also has a protective film web of a first material that extends at least along a portion of the first surface of the thin glass film. According to the invention, at least one reinforcing strip of a second material is provided that runs along at least one of the two thin glass film edges and is different from the first material, with the protective film web and the at least one reinforcing strip being connected to one another such that they can be applied together to the thin glass web. The at least one reinforcing strip also shows a higher relative tensile strength than the thin glass film web.

### DETAILED DESCRIPTION

First, a film web is understood to be a sheetlike structure whose dimensions in one spatial direction, i.e. height or thickness, are significantly smaller than in the other two spatial directions. The main extension is defined by length and width. In a film web, moreover, width and thickness are specified. As a rule, however, the length of the film is not specifically defined. The length of the film web is ordinarily at least 10 times greater than the width. The film web can have a simple continuous configuration, or it may also be interrupted. It can consist of a single material or areas of different materials, but can either have a constant thickness over its entire surface area or have areas of different thicknesses. The film web can consist of one or a plurality of layers that are arranged in congruent fashion, or may have an at least partially non-overlapping configuration.

A thin glass film web in understood to refer to a film web having a height of 10 to 200 μm, preferably 20 to 100 μm, more preferably 25 to 75 μm, and particularly preferably 30 to 50 μm. The entire thin glass film web is preferably composed of thin glass. Thin glass films are highly suitable as impermeable substrates. Examples of available thin glasses include D263 from Schott or Willow® Glass from Corning.

A borosilicate glass such as D263 T from Schott, an alkali-alkaline earth-silicate glass, or an aluminum borosilicate glass such as AF 32 eco, also from Schott, is preferably used for the thin glass film composite web according to the invention. An alkali-free thin glass such as AF 32 eco is advantageous because its UV transmission is greater. For UV-curing adhesive systems, therefore, initiators with absorption maxima in the UV-C range can be more favorably used, which increases the stability of the uncrosslinked adhesives with respect to daylight.

An alkali-free thin glass such as D263 T eco is advantageous because its thermal expansion coefficient is higher, and it is more compatible with the polymer components of an organoelectronic device such as an OLED unit.

Such thin glass can be manufactured by the down-draw process, as referenced in WO 00/41978 A1, or by methods such as those disclosed for example in EP 1832558 A1. In the former document, further methods are disclosed for producing composites of thin glass and polymer layers or films. In thin glass films or thin glass film webs, because of the intrinsically high barrier properties of the glass against oxygen and hydrogen, further barrier coating is unnecessary.

The protective film web of a first material extends along at least a portion of the first surface of the thin glass film web. The protective film web preferably covers the first surface completely or at least in some areas, and preferably at least along a strip on each of the two edges of the thin glass film web.

The first surface of the thin glass film web is preferably completely covered, because in this case, the protective film web protects the entire surface of the thin glass film web, for example against mechanical, chemical, or physical damage.

As the material of the protective film web of the thin glass film composite web according to the invention, sheetlike materials, papers, plastic-coated papers, or films can be used, with said films in particular being dimensionally stable plastic or metal films. Non-limiting examples thereof include metal films of aluminum or plastic films of polyolefins such as polyethylene (PE) or polypropylene (PP), cyclic olefin copolymers (COC), polyvinyl chloride (PVC), polyesters—particularly polyethylene terephthalate (PET) and polyethylene naphthalate (PEN), polymethyl pentene (PMP), ethylene vinyl alcohol (EVOH), polyvinylidene chloride (PVDC), fluoropolymers such as polyvinylidene fluoride (PVDF), polyacrylonitrile (PAN), polycarbonate (PC), polyamide (PA), polyether sulfone (PES), polyether imide (PEI), polyarylate (PAR), cellulose triacetate (TAC), polymethacrylate (PMMA), or polyimide (PI).

The protective film web preferably consists of polyesters, particularly polyethylene terephthalate, for example biaxially oriented polyethylene terephthalate, or polyolefins, particularly polybutene, cycloolefin copolymer, polymethyl pentene, polypropylene, or polyethylene, for example monoaxially oriented polypropylene, biaxially oriented polypropylene, or biaxially oriented polyethylene or copolymers thereof. Polyester films are advantageous in that they provide temperature stability and increased mechanical stability. Therefore, it is most particularly preferred for the protective film web to consist of a polyester film such as biaxially oriented polyethylene terephthalate. Polyolefins are advantageous because of their low water vapor permeation rate and reduced water content. Therefore, it is most particularly preferred for the protective film web to consist of a film comprising cycloolefin copolymer or polymethyl pentene, materials that also show higher temperature stability than other polyolefin films.

The protective film web may also be composed of composites, particularly layered composites, of the above-mentioned materials with one another or with other materials.

In a preferred embodiment, the protective film web has a barrier function. The barrier function prevents one or more specific permeate(s), particularly water vapor, from penetrating the thin glass film composite and promoting stress corrosion cracking in the thin glass web.

The barrier function is preferably provided by a barrier layer. The barrier layer is favorably configured on a surface of the protective film web, but can also be contained therein as a layer.

Such a barrier layer can consist of organic or inorganic materials, for example a metal layer, an organic layer, or a sol-gel layer.

The barrier layer is preferably provided on an inner side of the protective film web facing the glass film, as this allows better protection of the barrier layer from mechanical damage.

Particularly preferably, the protective film web comprises at least one inorganic barrier layer. Particularly suitable as inorganic barrier layers are metals deposited in a vacuum (for example by evaporation, CVD, PVD, or PECVD) or under atmospheric pressure (for example by means of atmospheric plasma, reactive corona discharge, or flame pyrolysis) such as aluminum, silver, gold, nickel, or particularly metal compounds such as metal oxides, nitrides, or hydronitrides, for example oxides or nitrides of silicon, boron, aluminum, zirconium, hafnium, or tellurium or indium tin oxide (ITO). Layers of the aforementioned variants doped with further elements are also suitable.

Examples of particularly suitable methods for applying an inorganic barrier layer include high-power impulse magnetron sputtering and atomic layer deposition, by means of which highly impermeable layers can be produced with low temperature stress on the protective film. Preferred is a permeation barrier of the protective film web having a barrier function or a composite of the protective film web and the barrier layer that has a water vapor transmission rate (WVTR) of <1 g/(m²·d) and/or an oxygen transmission rate (OTR) of <1 cm³/(m²·d·bar), with this value referring to the respective thickness of the protective film web having a barrier function, i.e., not being standardized to a specific thickness. Here, WVTR is measured at 38° C. and 90% relative humidity according to ASTM F-1249, and OTR is measured at 23° C. and 50% relative humidity according to DIN 53380 Part 3.

The reinforcing strips composed of a second material different from the first material are arranged along each or at least one of the two edges of the thin glass film web, preferably along its entire extension in the longitudinal direction. The reinforcing strips run essentially parallel, and preferably exactly parallel to the edge of the thin glass film web. In this case, the reinforcing strips run parallel to the ideal edge of the thin glass film web, as the real edge of the thin glass film web has tolerances in its straightness such as camber or edge waviness. The reinforcing strips have a specified width and thickness or height. Their length is as a rule not specifically defined, but is based on the length of the thin glass film web. The length of the reinforcing strips is preferably identical to the length of the thin glass film web.

The width and height of the reinforcing strips should preferably remain constant over the entire length of the reinforcing strips, i.e., the cross section should remain identical over the entire length. However, it is also conceivable to configure the height and/or width in a variable manner over said length.

The reinforcing strips can be configured along their entire length on the edge of the thin glass film web. However, the reinforcing strips can also be discontinuous over their length, for example if the glass film web consists of individual sections in the longitudinal direction, with the reinforcing strips being configured only along the edge of the thin glass film web.

According to the invention, the reinforcing strips of the protective film run only in the area of the edge of the thin glass film, i.e., the reinforcing strips do not extend in their width over the entire width of the thin glass film web and/or the protective film web. The sum of the widths of the reinforcing strips along one edge of the thin glass film web should be less than half the entire width of the thin glass film web, preferably less than a third, and particularly preferably less than a quarter of the entire width of the thin glass film web.

As at least one reinforcing strip runs along at least one of the two edges, the projection of the reinforcing strips parallel to the surface of the thin glass film web in the plane thereof will lie at last partially outside of the surface of the thin glass film web. Here, ‘partially outside’ also includes contact of the edge of the projection of the reinforcing strips with the edge of the thin glass film web. Preferably, the projection of the reinforcing strips lies outside the surface of the thin glass web with at least half of its area, and particularly preferably is completely outside the surface of the thin glass film web.

More clearly, this means that a reinforcing strip in the projection covers or is flush with (lies exactly on the edge of) the glass edge, or lies outside the thin glass film web adjacent to the glass edge. The projection of the reinforcing strips can also be at an external distance from the edge of the thin glass film web. The figures show both arrangements according to the invention and arrangements not according to the invention.

The reinforcing strips may have different external dimensions, particularly in width and height, and in their arrangement with respect to the edge of the thin glass film web.

The reinforcing strips are preferably arranged at a distance from the thin glass film edge, and said reinforcing strips are advantageously arranged along the entire length at a distance from the thin glass film edge. The distance allows tolerances in the straightness of the thin glass film web reinforcing strips, particularly camber and waviness of the edge of the thin glass film web, to be buffered. Within the separation zone between the reinforcing strips and the thin glass film web, an area is formed which consists solely of the partial area of the protective film web, is reinforced neither by the reinforcing strips nor the thin glass web itself, and as a rule shows greater flexibility than the reinforcing strips and the thin glass film web. This makes it possible to elastically buffer force peaks and web offset and to gently transfer unilateral stresses on the thin glass film composite web, for example by means of web edge control, to the thin glass film web without placing excessive stress on the thin glass film edge. The distance d is limited at its lower boundary by the usual tolerances in the straightness of the thin glass web. These are approximately 0.5 mm to 10 mm. In principle, the distance is not limited at its upper boundary, but a distance of 10 to 50 mm is preferred, because if the distance is greater, web guiding forces transferred to the reinforcing strips may lead to the formation of folds in the exposed area of the protective film web.

The reinforcing strips are preferably completely arranged in a space spanned by the intended lateral prolongation of the first and second surface of the thin glass film web, i.e. the thin glass film layer.

Preferably, the first and second surface of the thin glass film web have a planar configuration, and each forms one layer. The intended lateral projections of the layers beyond the respective edge of the thin glass film web open up a space in which the thin glass film is arranged, said space having a height corresponding to that of the thin glass film, which as a rule is not limited in its width, unless the two surfaces are inclined at angles to each other and intersect along a lateral line, and has a length corresponding to the length of the thin glass film composite web. This space is also referred to here as the thin glass film layer. Accordingly, a protective layer in which the protective film web is arranged is formed.

The reinforcing strips are preferably arranged completely within the thin glass film layer, which means that an outermost end or a free end of the reinforcing strips facing away from the protective film has a height above the protective film web that is equal to or less than the height of the second surface of the thin glass film web above the protective film web.

In a further preferred embodiment of the invention, an upper free side of the reinforcing strips aligns with the second surface of the thin glass film web. This allows the thin glass film composite web to be wound onto the roll without being offset along its width.

In another embodiment, the height of the reinforcing strips is greater than the height of the thin glass film web above the protective film web. This provides particularly rigid reinforcing strips. However, it is preferable if the height of the reinforcing strips is not greater than five times the thickness of the thin glass film web, and particularly preferably not greater than three times this thickness, as the bending stiffness will otherwise become too great, making it difficult to wind the thin glass film composite onto a roll.

The reinforcing strips can have cross-sectional areas that are of the same size and thus the same tensile strength but are nevertheless of different heights. The reinforcing strips with the greater height then have a higher bending stiffness.

In a further preferred embodiment of the invention, however, the height of the reinforcing strips is lower than the height of the thin glass film web, so that in this embodiment, lower bending stiffness is achieved, with the result that the thin glass film composite remains particularly flexible and can thus be favorably wound onto a roll using only minimal force.

In preferred embodiments of the invention, an adhesive layer, particularly a pressure-sensitive adhesive layer, is provided between the thin glass film web and the protective film web. The protective film web can enclose the adhesive layer, but it can also be separately applied to the glass film or the protective film. The adhesion may be provided by the protective film material itself or by a layer of an adhesive, preferably a pressure-sensitive adhesive or an activatable adhesive.

The protective film web can be coated with a fluid phase onto the thin glass film web or can be applied as a prefabricated layer, for example as a film, to the thin glass film web. The protective film web is advantageously an adhesive tape with at least one carrier material layer and at least one adhesive layer and is connected with at least one reinforcing strip.

According to the invention, the protective film web and the at least one reinforcing strip are connected to one another such that they can be applied together to the thin glass web. Applied together means that a composite of the protective film web and the reinforcing strips can first be formed, and this composite can then be brought into contact with the thin glass film web.

The reinforcing strips can be formed by introducing reinforcing material into a protective film web, particularly into the carrier material layer thereof, for example by methods such as coextrusion or pultrusion. Examples of suitable reinforcing materials include metal or carbon fibers, carbon nanotubes, graphene, and crystalline or amorphous mineral fibers. The introduced reinforcing materials should preferably have a higher elastic modulus than the thin glass, particularly an elastic modulus that is greater than that of the thin glass by a factor of 1.5. This makes it possible to produce reinforcing strips that are thin in height, which thus have a lesser overall effect on the bending flexibility of the composite.

The reinforcing strips can be applied as a further layer to the protective film web and bonded thereto. However, they can also be introduced into the protective film web in sections and thus form a further web within the protective film web. Production of the composite of the protective film web and the at least one reinforcing strip is preferably carried out before applying the protective film web to the thin glass film web, but it can also take place thereafter.

The configuration with the protective film web composed of the first material and the reinforcing strips composed of the second material means that the chemical or physical composition of the two webs is different. This difference can also result from the physical introduction of further components into the first material, causing this area as a whole, into which the components are introduced, to constitute a second material. For example, from a chemical standpoint, the second material can completely contain the first material. Nevertheless, the two materials as a whole show different elastic moduli. According to the invention, the reinforcing strips have a relative tensile strength that is at least equivalent to the relative tensile strength of the glass film web. Here, tensile strength is understood to refer to the elastic modulus multiplied by the cross-sectional area A of the reinforcing strips or the glass film web. The relative tensile strength relates to the respective web or the strip and is therefore equal to the tensile strength divided by the width B. If the cross-section of the reinforcing strip is not rectangular, the maximum width is taken as the width.

The reinforcing strips may by all means be configured with multiple layers or coatings. When the reinforcing strips are composed of multiple layers, the total tensile strength is equal to the total of the tensile strengths of the individual layers.

The elastic modulus of thin glass is approximately 70 to 80 GPa, which means that in order to achieve the relative tensile strength according to the invention in the reinforcing strips, the thickness of the reinforcing strips can be increased with respect to that of the glass film, or the elastic modulus of the second material is increased. As the thickness of the reinforcing strips should preferably not exceed the thickness of the thin glass film, because otherwise the thin glass films will not entirely cover the radially adjacent inner wraps of the roll on winding of the thin glass film composite web onto said roll, causing tensions in the roll, it is preferably provided that the elastic modulus of the reinforcing strips is greater than that of the thin glass.

Materials with an elastic modulus at 23° C. and relative humidity of 50% of more than 80 GPa, and particularly more than 100 GPa, are preferably used as the material of the reinforcing strips, as this allows the thickness of the reinforcing strips to be kept low, with the result that the bending flexibility of the entire composite of the thin glass film composite web is impaired to a lesser degree. The reinforcing materials can be provided as a continuous layer in fiber or plate form. They can essentially be present in the reinforcing strips as a pure material or embedded in a matrix material, for example a polymer, a metal, or a ceramic. In addition to metals, examples of known materials include S-glass fibers, carbon fibers, aramid fibers (such as Kevlar 49), carbon nanotubes, graphene, and crystalline or amorphous mineral fibers (such as Saffil aluminum oxide fibers). As the material of the reinforcing strips, a metal layer, for example in the form of a metal film or metal fibers, is preferably used. Because of their high elastic moduli, iron, steel, copper, brass, bronze, titanium, nickel, and alloys thereof are preferred. The elastic moduli of several fibers are shown below, with particular examples of suitable materials selected for the reinforcing strips being S-glass, alumina, carbon and Kevlar 49.

| | Density | Tensile strength | Elastic modulus |
|---|---|---|---|
| Material | (g/cm³) | (MPa) | (GPa) |
| E-glass | 2.55 | 2000 | 80 |
| S-glass | 2.49 | 4750 | 89 |
| Alumina (Saffil) | 3.28 | 1950 | 297 |
| Carbon | 2.00 | 2900 | 525 |
| Kevlar 29 | 1.44 | 2860 | 64 |
| Kevlar 49 | 1.44 | 3750 | 136 |

The relative tensile strength of the reinforcing strips is greater than the relative tensile strength of the protective film web.

The protective film web is preferably glued onto the thin glass film web with an adhesive.

The adhesive applied to the protective film web is preferably a pressure-sensitive adhesive or an activatable adhesive, particularly a reversible and/or transparent adhesive. Particularly preferably, the adhesive placed on the carrier material layer is a pressure-sensitive adhesive.

Pressure-sensitive adhesives are adhesives whose cured film remains permanently tacky and adherent at room temperature in a dry state. Pressure-sensitive adhesives allow lasting bonding to the adhesive substrate with only relatively weak application pressure.

A distinction is generally made between pressure-sensitive adhesives for permanent applications and for reversible applications (reversibly configured pressure-sensitive adhesives). While the former generally can only be removed using a high degree of force and often with destruction of the adhesive substrate or the adhesive tape, the latter can generally be completely removed with relatively little force, leaving no residue, and without destroying the adhesive substrate.

According to the invention, the adhesive on the protective film web of the adhesive tape used in the method according to the invention is preferably reversibly configured.

The reversibility of a pressure-sensitive adhesive can be described by means of its viscoelastic properties.

In terms of its viscoelastic properties, a substance is generally considered suitable for pressure-sensitive adhesive applications if the memory modulus G′ is in the range of 10³ to 10⁶ Pa and the loss modulus G″ is also in this range at room temperature in the frequency range of 10° to 10¹ rad/s, and ideally 10⁻¹ to 10² rad/s. Within this range, which can also be referred to in a matrix plot of G′ and G″ (G′ plotted against G″) as the viscoelastic window for pressure-sensitive adhesive applications or as the pressure-sensitive adhesive window according to viscoelastic criteria, there are also various sectors or quadrants that more specifically characterize the expected pressure-sensitive adhesive properties of the relevant substances. According to Chang (J. Adhesion, 1991, Vol. 34, pp. 189-200), reversible pressure-sensitive adhesives are characterized by G′ in the range of 10³ to 3×10⁴ Pa and G″ in the range of 10³ to 3×10⁴ Pa at room temperature and a measurement frequency of 10⁻² rad/s respectively.

Here, the memory modulus and loss modulus of pressure-sensitive adhesives are determined in an oscillatory shear test (dynamic mechanical analysis, DMA) under torsional loading at a temperature of 23° C. and a frequency of 0.01 rad/s. This test is used to investigate rheological properties and is described in detail in Pahl et al., “Practical Rheology of Plastics and Elastomers,” VDI Publishing, 1995, pp. 57-60 and 119-127). The test is conducted in a shear rate-controlled rheometer under torsional loading using a plate-plate geometry with a plate diameter of 25 mm.

Generally speaking, according to the invention, an adhesive is preferably to be considered reversible if it shows an adhesive strength on steel of <3 N/cm, and preferably <2.2 N/cm.

According to the invention, all pressure-sensitive adhesives known to the person skilled in the art may be used, with examples including those based on acrylate and/or methacrylates, polyurethanes, natural rubbers, and synthetic rubbers; styrene block copolymer adhesives having an elastomer block of unsaturated or hydrogenated polydiene blocks such as polybutadiene, polyisoprene, copolymers of the two, polybutylene, particularly polyisobutylene, as well as elastomer blocks known to the person skilled in the art; polyolefins, particularly poly-α-olefins and/or polyisobutylenes; and fluoropolymers and/or silicones. The term “pressure-sensitive adhesive” also includes other adhesives possessing pressure-sensitive adhesive properties, as described in the “Handbook of Pressure Sensitive Adhesive Technology” by Donatas Satas (Satas & Associates, Warwick 1999).

When the term acrylate-based pressure-sensitive adhesives is used in this specification, it is also understood to comprise pressure-sensitive adhesives based on methacrylates or acrylates and methacrylates, without these having to be further specified, unless expressly stated otherwise.

Adhesive systems in which the generation of adhesive force in general is carried out by increasing or reducing the adhesive force using energy input, such as actinic radiation or heat, or by means of a material interaction, are considered to be activatable adhesives. This activation is preferably used in order to make the adhesive bonding reversible, particularly in cases where a pressure-sensitive adhesive does not fall into the category of reversible pressure-sensitive adhesives prior to its activation (Chang, J. Adhesion, 1991, Vol. 34, pp. 189-200). For example, such activatable pressure-sensitive adhesives are known from the area of grinding and dicing of adhesive tapes used in wafer processing.

In general, all commonly-used activated adhesive systems can be used as activatable adhesives. According to the invention, this activation is generally carried out by means of energy input, for example and particularly preferably using actinic radiation or heat (heat-activated debondable adhesives).

According to the invention, so-called “autoadhesive” layers are also considered to be reversibly configured pressure-sensitive adhesives. Autoadhesive layers are used for example in protective films for displays. They show very little or no initial tack and adhere particularly well to extremely smooth surfaces. Autoadhesive layers are described for example in WO 2005/044560 A1 or DE 19742805 A1.

The adhesive preferably contains at least one silane. Silanes are often used as coupling agents in order to increase adhesive bonding to glass. Examples are presented in U.S. Pat. No. 6,195,608, WO 2008/036222 A1, JP 2000-003782 A1, U.S. Pat. No. 6,501,014 B1, WO 2011/084323 A1, and EP 0924761 A1. The silane is not only applied to the thin glass film web prior to adhesion, but may also be contained in the adhesive itself. Silanes may be used that contain chemical groups which show favorable compatibility with the adhesive, or can even form covalent, ionic, or coordinative bonds with the adhesive. In cases where the protective film web adheres permanently to the thin glass film web, the adhesive preferably contains a silane showing favorable compatibility with said adhesive. In another embodiment of the invention in which the protective film web is again detached from the thin glass film web, reversible adhesives are used. These may contain a silane that is incompatible with the adhesive or a silane that cannot form covalent, ionic, or coordinative bonds with the adhesive. This largely prevents any increase in the adhesion of the reversible adhesive to the thin glass film web. Because of the incompatibility of the silane with the adhesive, the silane molecules capable of migration are deposited on the surface of the adhesive and therefore come into contact with the glass film web in large amounts. By means of the silane film formed in this manner on the second surface of the thin glass film web, microcracks can even be bridged over, improving the stability of the glass. The adhesive preferably contains a hydrophobic silane, with the term hydrophobic silane referring here to silanes with more than eight connected carbon atoms, such as octadecyldimethyl chlorosilane.

The invention also concerns a method for the storage of thin glass film webs, in which
the thin glass film web is provided with a first and a second surface and two edges running in a longitudinal direction,
a protective film web of a first material is applied along at least a portion of the first surface, and
at least one reinforcing strip of a second material that is different from the first material and has a higher relative tensile strength than the thin glass film web is arranged along at least one of the two edges,
wherein the protective film web and reinforcing strips are connected to one another such that they can be applied together to the thin glass web.

Advantageous variants can be found in the attached claims 18 to 26.

A method is further disclosed in which the area of the protective film containing the reinforcing zones is removed after processing or handling of the glass film, for example in a roll-to-roll process. Other areas of the protective film remain at least temporarily on the glass. The other areas should preferably remain on the glass web permanently. In this way, the glass film can be provided with a permanent protective film whose reinforcing zones remain in the composite material only temporarily. In this method, it is particularly preferred for the reinforcing zones to be arranged adjacent to the glass web so that they can be removed simply by cutting them off along the web.

### BRIEF DESCRIPTION OF THE DRAWINGS

The invention is described in several embodiments in 18 figures which show the following:

FIGS. 1 through 3 each show a thin glass film composite web according to the invention with a thin glass film web and protective film webs applied along the entire area of a first surface and two lateral glass-side reinforcing strips,

FIG. 4 shows a thin glass film composite web with a discontinuous protective film web and two lateral glass side reinforcing strips,

FIGS. 5 through 7 each show a thin glass film composite web with a protective film web and two lateral glass side reinforcing strips,

FIGS. 8 through 13 each show a thin glass film composite web with two lateral reinforcing strips arranged in the protective film layer,

FIGS. 14 through 16 each show a thin glass film composite web with a plurality of protective film webs,

FIGS. 17 and 18 each show a thin glass film composite web with a protective film web having two lateral glass side reinforcing strips that is connected to the glass film web by means of an adhesive layer,

FIGS. 19 and 20 each show embodiments not according to the invention of the thin glass film composite web, wherein the reinforcing strips do not run along at least one of the two edges of the thin glass film web,

FIG. 21 shows a further thin glass film composite web with two lateral reinforcing strips arranged in the protective film layer,

FIG. 22 shows a thin glass film composite web with a protective film web and two lateral reinforcing strips, which are arranged both in the protective film web layer and on the glass side and the side away from the glass, and

FIG. 23 shows an embodiment of the thin glass film composite web not according to the invention in which the protective film web and the reinforcing strips cannot be applied together.

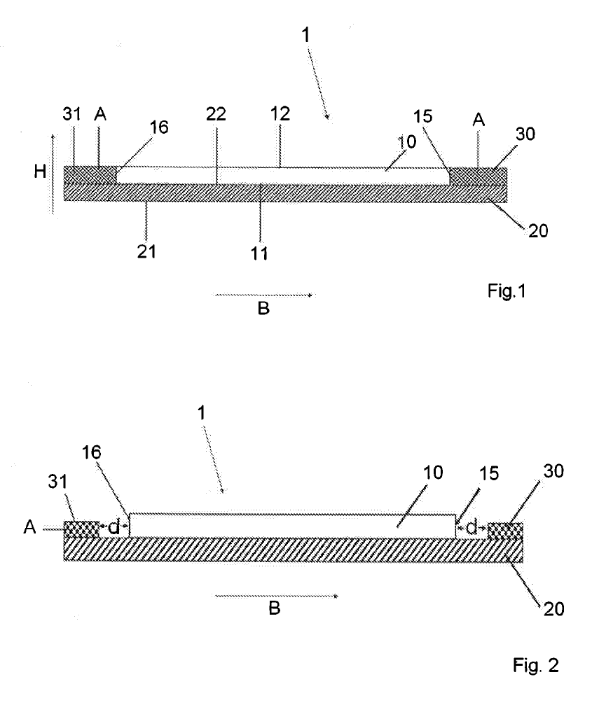

FIG. 1 shows a structure of a thin glass film composite web 1 according to the invention with a thin glass film web 10, a protective film web 20, and two lateral reinforcing strips 30, 31. The thin glass film composite web extends to a great length in the longitudinal direction L. The figures consistently show a width B of the thin glass film composite web 1 arranged perpendicular to the longitudinal direction.

The thin glass film web 10 has a first surface 11 and a second surface 12. A second surface 22 of the protective film web 20 is applied to completely cover the first surface 11. “Completely cover” in this case means that the first surface 11 of the thin glass film web 10 is completely covered by the protective film web 20.

The protective film web 20 projects laterally along width B on both sides beyond the thin glass film web 10. The thin glass film web 10 shows two lateral edges 15, 16 running in a longitudinal direction L. The two edges 15, 16 are highly sensitive, because as in this case, thin glass film webs 10 ordinarily have a thickened border on the longitudinal sides after production which is cut from the thin glass film web 10 in the longitudinal direction L for better handling of said thin glass film web 10. The resulting cut edges 15, 16 of the thin glass film web 10 according to FIG. 1 are therefore highly sensitive and must be protected. In particular, the thin glass film webs 10 are wound onto rolls in order to be transported or stored. When the thin glass film web 10 is subjected to further processing, handling of the thin glass film web 10 gives rise to forces at the two edges 15, 16 of the thin glass film web 10 that can lead to crack formation, in particular due to tensile forces in a longitudinal direction L of the thin glass film web 10. Another factor in handling of the thin glass film web 10 are contacts with the edges that can also lead to crack formation.

In the embodiment according to FIG. 1, one each of the reinforcing strips 30, 31 is applied to the second surface 22 of the protective film web 20 in the plane of the thin glass film web 10 along the two edges 15, 16 over the entire longitudinal direction L of said edges 15, 16. The reinforcing strips 30, 31 are positioned respectively in direct contact with the edges 15, 16 of the thin glass film web 10 on both sides. The reinforcing strips 30, 31 are at a height H above the protective film web 20 that corresponds exactly to the height H of the thin glass film web 10. The cross sections of both the two reinforcing strips 30, 31 and the thin glass film web 10 show a constant height H over the entire width B. The height H also remains constant along the longitudinal direction L. Each of the reinforcing strips 30, 31 is composed of one of the above-described materials with an elastic modulus that is greater than that of the thin glass film web 10. As a result, the reinforcing strips 30, 31 have a higher relative tensile strength in the longitudinal direction L, and tensile forces acting in the longitudinal direction L on the thin glass film composite web of FIG. 1 no longer reach the edges 15, 16 of the thin glass film web 10, but are absorbed by the respective reinforcing strips 30, 31. The thin glass film composite web 1 according to FIG. 1 is particularly well-suited for the storage of the thin glass film web 10 on a roll, because the thin glass film web 10 lies with its entire surface against the protective film web 20 of the radially adjacent inner wrap.

FIG. 2 shows an embodiment of the thin glass film composite web 1 according to the invention in which the two reinforcing strips 30, 31 are applied to a first surface 21 of the protective film web 20 facing toward the thin glass film web 10 at a distance d from the edges 15, 16 of the thin glass film web 10. The cross sections of the reinforcing strips 30, 31 of the embodiments of the thin glass film composite web 1 in FIGS. 2 and 1 are of the same size. As a result, the tensile strength that is the product of the elastic modulus and a cross-sectional area A of the respective reinforcing strips 30, 31 is also identical. However, the shape of the cross-sectional area A of the reinforcing strips 30, 31 in FIG. 2 is different from that of FIG. 1. The reinforcing strips 30, 31 in FIG. 2 have a greater height H and a lesser width B than the reinforcing strips 30, 31 in FIG. 1, and the reinforcing strips 30, 31 of FIG. 2 in particular have a greater height than that of the thin glass film web 10. On winding the thin glass film composite web 1 onto a roll according to FIG. 2, the resulting bending stiffness is greater than that of the thin glass film composite web 1 according to FIG. 1, because the reinforcing strips 30, 31 of FIG. 2 have a greater height H than those of FIG. 1. Although this causes the drawback that the thin glass film composite web 1 of FIG. 2 can only be wound onto a roll having a larger radius, the thin glass film composite web 1 according to FIG. 2 has the advantage that the reinforcing strips 30, 31 and the thin glass film web 10 are not in direct contact with one another, so that tolerances such as camber and roughness of the edges 15, 16 of the thin glass film web 10 and corresponding irregularities of the edges of the reinforcing strips 30, 31 are compensated for. A further advantage is that when the thin glass web and the protective film to which the reinforcing strips are connected are brought together, the glass film edge is not touched by the reinforcing strips, thus reducing the risk of crack formation. When wound onto a roll, the thin glass film web 10 no longer fully covers the protective film web 20 of the adjacent radial inner wrap.

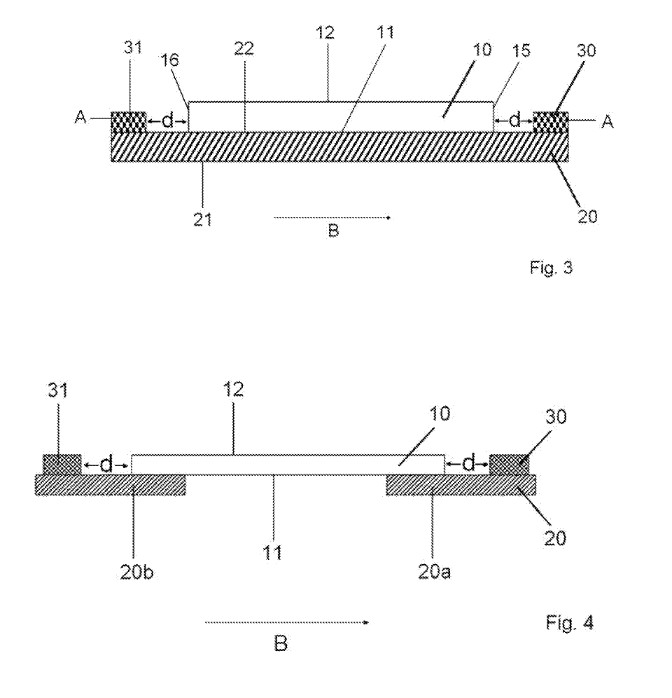

In the embodiment of the thin glass film composite web of the invention 1 according to FIG. 3, the thin glass film web 10 again has the protective film web 20 glued along its entire first surface 11. The protective film web 20 extends out on both sides along the width B beyond the edges 15, 16 of the thin glass film web 10. On the second surface 22 of the protective film web 20, one of the reinforcing strips 30, 31 each is applied at the two edges 15, 16. According to the embodiment of FIG. 3, the reinforcing strips 30, 31 are composed of a material that has a higher elastic modulus than the materials of the reinforcing strips 30, 31 of FIGS. 1 and 2. This makes it possible to configure the reinforcing strips 30, 31 in the embodiment of FIG. 3 with a smaller cross-sectional area A, and particularly with a lower height H, but they still have the same relative tensile strength as the reinforcing strips 30, 31 of the embodiments of FIGS. 1 and 2. In this case as well, the two reinforcing strips 30, 31 run in the longitudinal direction L at respective distances d from the edges 15, 16 of the thin glass film web.

An advantage of the embodiment of FIG. 3 is its low bending stiffness, which makes it possible to keep the bending radius small and thus allow easy and tight winding of the thin glass film composite web 1 onto a roll. In addition, the thin glass film web 10 completely covers the protective film web 20 of the respectively adjacent wrap of the roll.

FIG. 4 shows an embodiment in which the protective film web 20 is cross-sectionally configured along the width B in a discontinuous manner. The protective film web 20 is composed of two protective film web strips 20a, 20b that are applied in the area of the edges 15, 16 in the longitudinal direction L to the first surface 11 of the thin glass film web 10, preferably using an adhesive. In a thin glass film layer, one of the reinforcing strips 30, 31 each is applied along the two edges 15, 16. Both reinforcing strips 30, 31 are configured along the edges 15, 16 at a distance d from said edges 15, 16 and have the same height H as the glass film web.

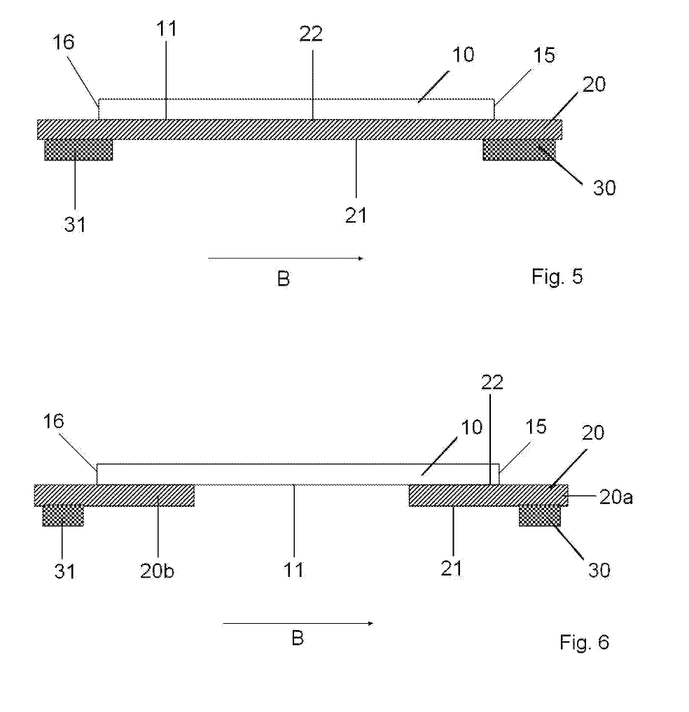

FIGS. 5, 6 and 7 show the thin glass film composite web 1 with a protective film web 20 applied to the first surface that can be discontinuous along its width B according to the embodiment of FIG. 6. In all three embodiments, however, the reinforcing strips 30, 31 are applied not to the second surface 22 of the respective film web 20, to which the thin glass film web 10 is also applied, but to the first surface 21 opposite thereto. The reinforcing strips 30, 31 are thus provided on the protective film web 20 opposite the thin glass film web 10. The protective film web 20 can extend out laterally along width B beyond the two edges 15, 16 of the thin glass film web 10. Here, the protective film web 20 can be discontinous along width B, as shown in FIG. 6, and may have the two protective film web strips 20a, 20b.

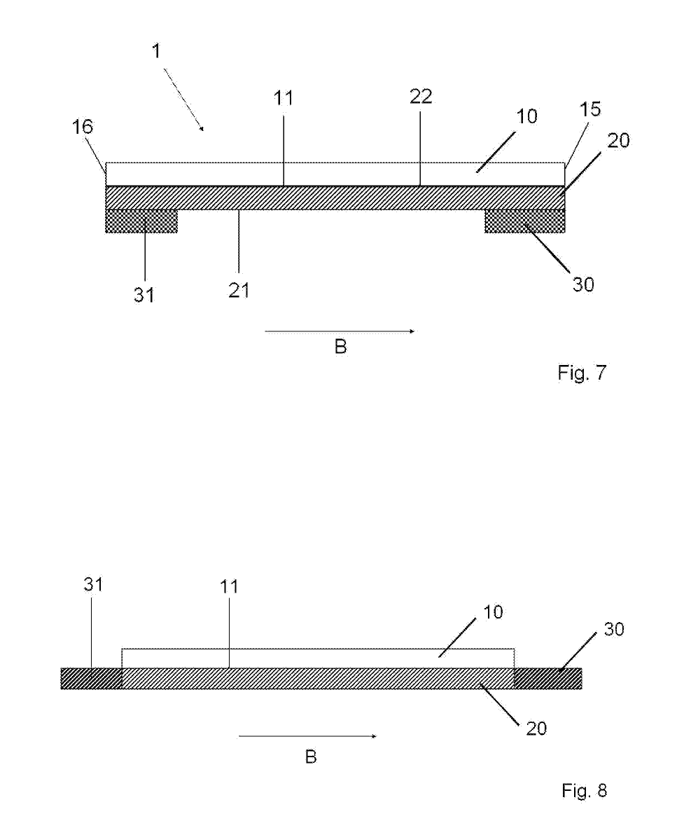

In the embodiments of FIGS. 5, 6, and 7, the two reinforcing strips 30, 31 are applied to the first surface 21 of the protective film web 20 in the longitudinal direction L. FIG. 7 shows an embodiment in which the edges the protective film web 20 and the outer edges of the reinforcing strips 30, 31 are aligned with one another at the edges 15, 16 of the thin glass film web 10 and laterally form a planar boundary of the thin glass film composite web 1.

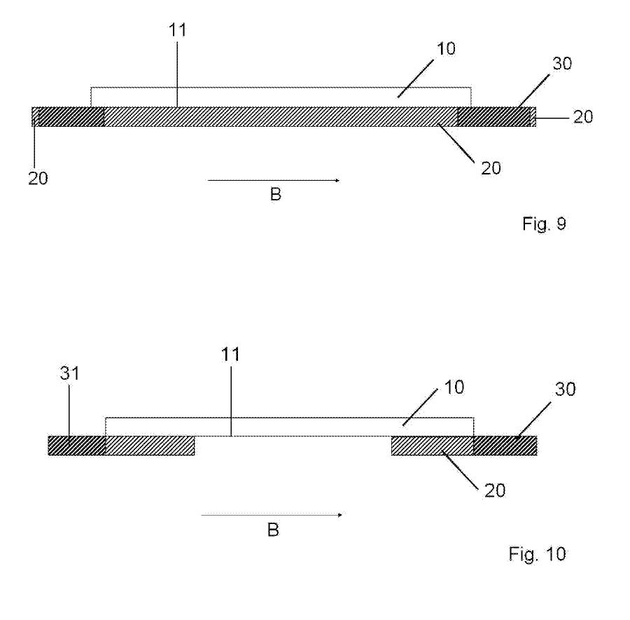

FIGS. 8 through 11 show embodiments of the thin glass film composite web according to the invention 1 in which the reinforcing strips 30, 31 are arranged not in the thin glass film layer, but in the protective film layer. Here, the protective film web 20 can again be of a single piece in the cross section parallel to the longitudinal direction L, i.e. completely covering the first surface 11 of the thin glass film web 10, or can be configured with multiple webs according to FIG. 10. The two reinforcing strips 30, 31 are in contact from the bottom with the thin glass film web 10 along the first surface 11 in the embodiments according to FIGS. 9 and 11 and extend somewhat farther, or they can be exactly congruent with the edges 15, 16 of the thin glass film web 10, as shown in the embodiments in FIG. 8 and FIG. 10. In the embodiment of FIG. 9, the two reinforcing strips 30, 31 are integrated into the protective film web 20 along the width B, so that the two outer edges of the thin glass film composite web 1 along the width B are formed by the protective film web 20. The height H of the reinforcing strips 30, 31 is exactly the same as the height H of the protective film web 20.

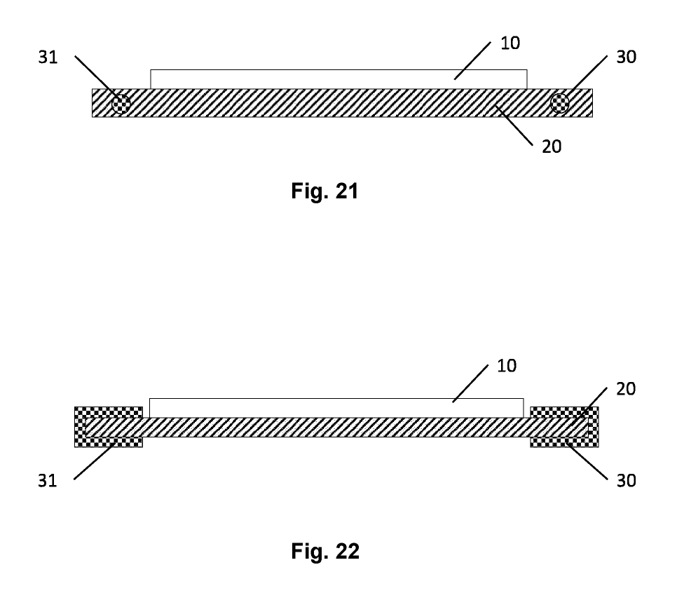

FIG. 21 shows an embodiment of the thin glass film composite web according to the invention corresponding to the embodiments of FIGS. 8 through 11 in which the reinforcing strips 30, 31 are configured with a height less than the height H of the protective film web.

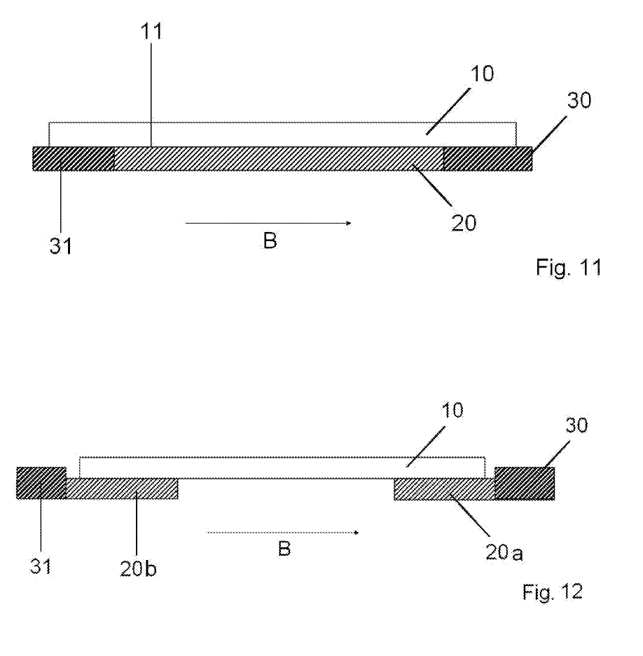

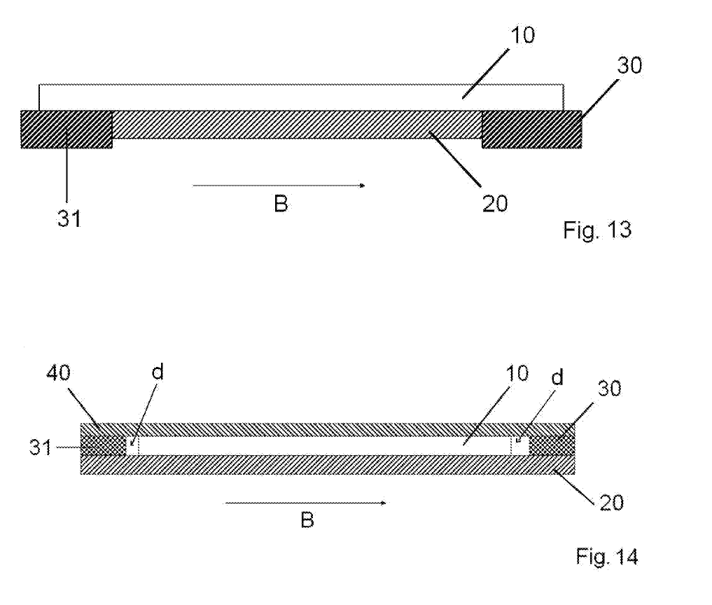

FIGS. 12 and 13 show embodiments of the thin glass film composite web 1 according to the invention in which the two reinforcing strips 30, 31 have a greater height H than the protective film web 20. The reinforcing strips 30, 31 can run laterally adjacent to the protective film web 20 and extend in the direction of the thin glass film web 10 beyond the protective film web 20, or according to FIG. 13, may extend in a direction away from the glass film web 10 beyond the protective film web 20.

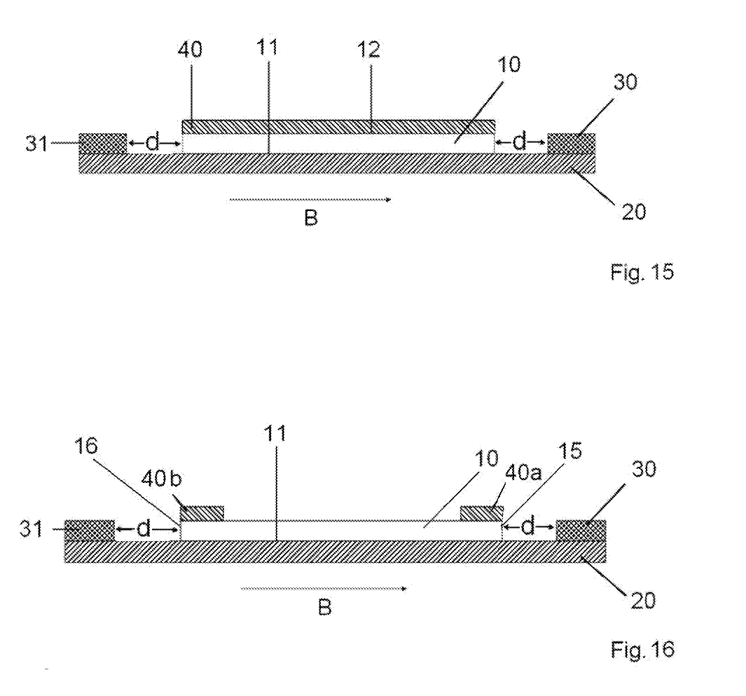

FIGS. 14, 15 and 16 show an embodiment of the thin glass film composite web 1 according to the invention with the thin glass film web 10 and the two reinforcing strips 30, 31 in the thin glass film layer as well as the protective film web 20, which is applied to the first surface 11 of the thin glass film web 10. On the second surface 12 of the thin glass film web 10, a further protective film web 40 is applied in the embodiment according to FIGS. 14 and 15, and in the embodiment according to FIG. 16, two further protective film web strips 40a, 40b are applied along the two edges 15, 16. However, neither the protective film web 40 nor the two further protective film web strips 40a, 40b have any reinforced areas.

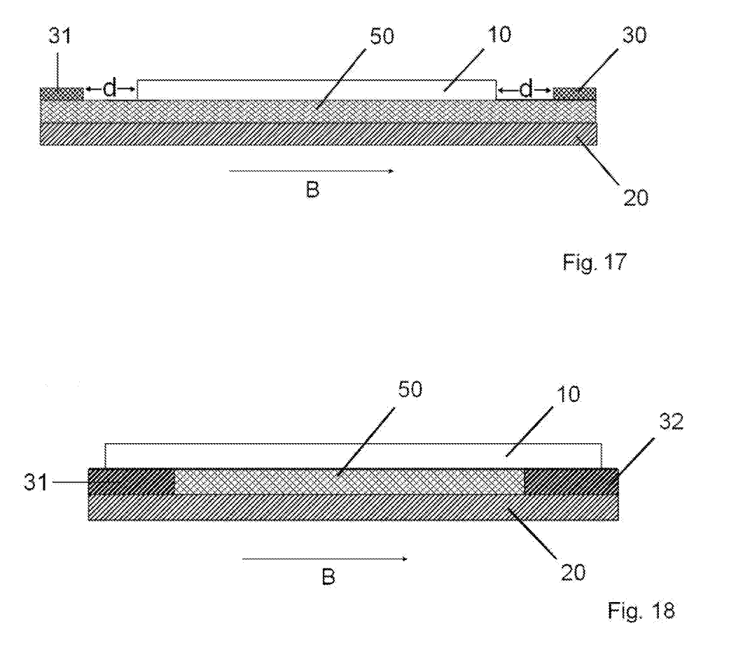

FIGS. 17 and 18 show an embodiment according to FIG. 3 or FIG. 11 in which, however, an adhesive layer 50 between the protective film web 20 and thin glass film web 10 or the two reinforcing strips 30, 31 is clearly shown. In general, adhesive layers 50 may be provided in all of the above embodiments between the thin glass film web 10 and the protective film web 20 and between the reinforcing strips 30, 31 and the protective film web 20. These adhesive layers 50 may be reversible or permanent with respect to the thin glass film web 10. They may contain silanes in order to counteract crack formation in the thin glass film web 10 or even to repair said cracks.

FIG. 22 shows an embodiment of the thin glass film composite web of the invention according to the embodiments in FIGS. 3, 6, and 8, wherein the reinforcing strips 30, 31 are folded around the edge of the protective film web and are thus arranged in the plane of the protective film web both on the glass side on the protective film web and on the side facing away from the glass on the protective film web.

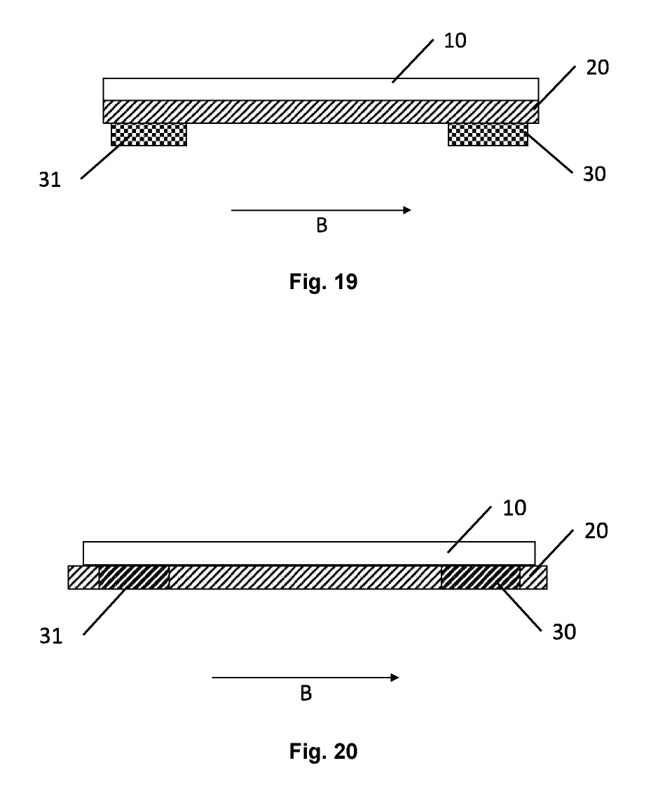

FIG. 19 is an embodiment of a thin glass film composite web 1 not according to the invention in which the thin glass web 10 is entirely covered with a protective film web 20 that has reinforcing strips 30, 31 on the surface of said protective film web 20 opposite the glass side. In this case, the projections of the reinforcing strips 30, 31 perpendicular to the surface of the thin glass film web 10 in the plane thereof are completely within the area of the thin glass film web 10 and are thus arranged at a distance from the glass edge. In this arrangement, it is primarily the glass edge that is exposed to lateral longitudinal loads and is therefore at high risk of breakage.

FIG. 20 also shows an embodiment of a thin glass film composite web 1 not according to the invention in which the reinforcing strips 30, 31 are arranged in the plane of the protective film layer. The protective film 20 is configured as a single piece in a cross section perpendicular to the longitudinal direction L. The projections of the reinforcing strips 30, 31 perpendicular to the surface of the thin glass film web 10 in the plane thereof are completely within the area of the thin glass film web 10 and are thus arranged at a distance from the glass edge. In this arrangement as well, it is primarily the glass edge that is exposed to lateral longitudinal loads and is therefore at high risk of breakage.

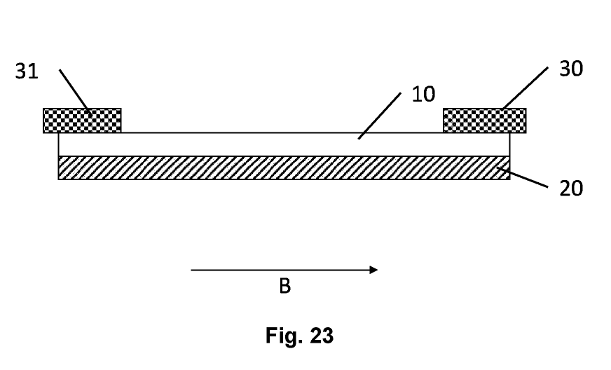

FIG. 23 shows an embodiment of the thin glass film composite web 1 not according to the invention in which the protective film web 20 and the reinforcing strips 30, 31 cannot be applied together. In this case, they are arranged on different sides of the thin glass film web 10. It is therefore initially impossible to produce a composite of the protective film web 20 and reinforcing strips 30, 31 that could then be brought into contact with the thin glass film web 10.

In an advantageous method, the protective film web is separated from the thin glass film together with the at least one reinforcing strip after use of the thin glass film composite, for example for constructing or encapsulation of an electronic device. In this case, the use of a non-permanent adhesive is advantageous.

In a further advantageous method, only the at least one reinforcing strip is separated from the thin glass film after use of the thin glass film composite, wherein a part of the protective film is optionally also separated. This can take place, for example, by lateral edge cutting. Particularly well-suited for this purpose are structures in which the reinforcing strip is arranged at a distance from the thin glass edge, for example according to FIGS. 2 to 4, and particularly 2 through 4, 6, 12 and 14 through 17, as in this case the reinforcing strips can be separated by means of a simple continuous vertical cut, without it being necessary to cut the thin glass web itself.

### LIST OF REFERENCE SYMBOLS

1 thin glass film composite web
10 thin glass film web
11 first surface of the thin glass film web
12 second surface of the thin glass film web
15 edge of the thin glass film web
16 edge of the thin glass film web
20 protective film web
20a protective film web strip
20b protective film web strip
21 first surface of the protective film web
22 second surface of the protective film web
30 reinforcing strips
31 reinforcing strips
40 further protective film web
40a protective film web strip
40b protective film web strip
50 adhesive layer
d distance
A cross-sectional area
B width
H height
L longitudinal direction

1. A thin glass film composite web with a thin glass film web having a first and a second surface and two edges running in a longitudinal direction and a protective film web of a first material extending along a least a portion of the first surface,
wherein
at least one reinforcing strip running along at least one of the two edges of a second material that is different from the first material, wherein the protective film web and the reinforcing strips are connected to one another such that they can be applied together to the thin glass web, and wherein the at least one reinforcing strip has a higher relative tensile strength than the thin glass film web.

2. The thin glass film composite web as claimed in claim 1, wherein
the at least one reinforcing strip has an elastic modulus E of greater than 80 GPa.

3. The thin glass film composite web as claimed in claim 2, wherein
the elastic modulus E is greater than 100 GPa.

4. The thin glass film composite web as claimed in claim 1, wherein
the second material is S-glass fibers, carbon fibers, aramid fibers, carbon nanotubes, graphene, or crystalline or amorphous mineral fibers and/or a metal layer comprising iron, steel, copper, brass, bronze, titanium, nickel and alloys thereof.

5. The thin glass film composite web as claimed in claim 1, wherein
the first material comprises polyethylene terephthalate, polybutene, cycloolefin copolymer, polymethyl pentene, polypropylene, or polyethylene or copolymers thereof.

6. The thin glass film composite web as claimed in claim 1, wherein
the protective film web extends entirely over the first surface and/or extends along a width on both edges of the thin glass film web beyond said edges.

7. The thin glass film composite web as claimed in claim 1, wherein
one each of the reinforcing strips is arranged along the edges of the thin glass film web along the entire longitudinal direction (L) of the edges on the second side of the protective film web facing toward the thin glass film.

8. The thin glass film composite web as claimed in claim 1, wherein
the at least one reinforcing strip is arranged at a distance from the edges of the thin glass film web.

9. The thin glass film composite web as claimed in claim 1, wherein
the at least one reinforcing strip has an equal or lower height (H) above the protective film web than the second surface of the thin glass film web.

10. The thin glass film composite web as claimed in claim 1, wherein
the at least one reinforcing strip is arranged at least partially, and optionally entirely, in the thin glass film layer.

11. The thin glass film composite web as claimed in claim 1, wherein
the at least one reinforcing strip is arranged on a first side of the protective film web facing away from the thin glass film web.

12. The thin glass film composite web as claimed in claim 1, wherein
the at least one reinforcing strip is arranged at least partially, and optionally entirely, in the protective film web layer.

13. The thin glass film composite web as claimed in claim 1, wherein
at least one further protective film web is present on the second surface of the thin glass film web.

14. The thin glass film composite web as claimed in claim 1, wherein
an adhesive layer, optionally a pressure-sensitive adhesive layer, is arranged between the thin glass film web and the protective film web.

15. The thin glass film composite web as claimed in claim 13, wherein
the protective film web is connected by means of adhesive tape to at least one carrier material layer, at least one adhesive layer, and at least one reinforcing strip.

16. The thin glass film composite web as claimed in claim 1, wherein
the protective film web comprises a barrier function and thus has a water vapor permeation rate of less than 1 g/m² d at 38° C. and 90% relative humidity.

17. A method for the storage of a thin glass film web, wherein
the thin glass film web is provided with a first and a second surface and two edges running in a longitudinal direction, a protective film web of a first material is applied along at least a portion of the first surface,
and at least one reinforcing strip of a second material that is different from the first material and has a higher relative tensile strength than the thin glass film web is arranged along at least one of the two edges, wherein the protective film web and reinforcing strips are connected to one another such that they can be applied together to the thin glass web.

18. The method as claimed in claim 17,
wherein
the protective film web is provided with the reinforcing strips.

19. The method as claimed in claim 17,
wherein
S-glass fibers, carbon fibers, aramid fibers, carbon nanotubes, graphene, or crystalline or amorphous mineral fibers and/or a metal layer comprising iron, steel, copper, brass, bronze, titanium, nickel and alloys thereof are used as the second material.

20. The method as claimed in claim 17, wherein
polyethylene terephthalate, polybutene, cycloolefin copolymer, polymethyl pentene, polypropylene or polyethylene or copolymers thereof are used as the first material.

21. The method as claimed in claim 17, wherein
a thin glass film composite web of a thin glass film web and a glued-on protective film web are rolled up and then unrolled and the at least one reinforcing strip is separated from the thin glass film composite, but at least a part of the protective film web remains on the thin glass film web.

22. The method as claimed in claim 21, wherein
the thin glass film composite web (1) composed of the thin glass film web (10) and the glued-on protective film web are rolled up and then unrolled and the protective film web is then removed from the thin glass film web.

23. The method as claimed in claim 22, wherein
the protective film web is provided on its second surface with an adhesive and is glued onto the first surface of the thin glass film web.

24. The method as claimed in claim 23,
wherein
the adhesive contains a silane that is incompatible therewith.

25. The method as claimed in claim 24, wherein
multiple protective film webs are applied to the thin glass film web, and not all of the protective film webs are again removed from the thin glass film web.

26. The method as claimed in claim 21, wherein
only the at least one reinforcing strip is separated from the thin glass composite after use of said thin glass film composite, wherein a part of the protective film web is optionally also removed.
